(19) United States
(12) Patent Application Publication
(10) Pub. No.: US 2026/0203479 A1
(43) Pub. Date: Jul. 16, 2026

(54) METHODS OF WIRELINE CONVEYANCE MODELING POWERED BY A PHYSICS-INFORMED NEURAL NETWORK

(71) Applicant: Schlumberger Technology Corporation, Sugar Land, TX (US)

(72) Inventors: Benjamin Jean Yvon Durand, Sugar Land, TX (US); Nikolay Baklanov, Sugar Land, TX (US); Zhandos Ombayev, Sugar Land, TX (US); Jiacheng Wang, Sugar Land, TX (US)

(21) Appl. No.: 19/449,548

(22) Filed: Jan. 15, 2026

Related U.S. Application Data
(60) Provisional application No. 63/745,466, filed on Jan. 15, 2025.

(51) Int. Cl. G06F 30/27; E21B 47/12; G06N 3/08

(52) U.S. Cl. CPC G06F 30/27; E21B 47/12; G06N 3/08

(57) ABSTRACT

A system including computer-readable storage media and a processing system configured to execute instructions stored on the computer-readable storage media. Executing the one or more instructions causes the processing system to process a request to predict one or more parameters associated with a geological region; access a physics-based model associated with a downhole operation, the geological region, or both; and integrate the physics-based model with a neural network model to generate a physics-informed neural network (PINN) model associated with the downhole operation in the geological region.

### CROSS-REFERENCE TO RELATED APPLICATIONS

This application claims the benefit of, and priority to, U.S. Patent Application No. 63/745,466, entitled “WIRELINE CONVEYANCE MODELING”, filed Jan. 15, 2025, which is incorporated herein by this reference in its entirety.

### BACKGROUND

Aspects of the present disclosure generally relate to wireline conveyance modeling powered by a neural network. More specifically, some aspects of the present disclosure are generally related to wireline conveyance modeling powered by a physics-informed neural network (PINN).

Producing hydrocarbons from a well drilled into a geological formation is a remarkably complex endeavor. During certain operations, such as well production operations, it may be beneficial or even necessary to employ a wireline conveyance model to perform various operations such as well logging, maintenance, interventions, perforation, and the like. Accurately estimating the interaction between the tool string, the cable, the borehole, and the well may be helpful for determining wireline conveyance selections, operational designs, and risk evaluations. Accordingly, accurate predictions generated from wireline conveyance models may improve job design and increase the likelihood of successful operations. However, existing models for predicting the interactions between the downhole tool string, the cable, the borehole, and the well may suffer from inaccuracies due to system complexities and uncertain input parameters, such as friction coefficients.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In some embodiments, a method may include receiving a request to predict one or more parameters associated with a geological region, receiving a physics-based model associated with performing a downhole operation of the geological region, and integrating the physics-based model with a neural network model to generate a physics-informed neural network (PINN) model associated with the geological region via a processing system.

In some embodiments, a system including computer-readable storage media storing one or more instructions and a processing system coupled to the computer-readable storage media and configured to execute the one or more instructions. Executing one or more instructions cause the processing system to receive or generate a request to predict one or more parameters associated with the geological region, access a physics-based model associated with performing a downhole operation in the geological region, and integrate the physics-based model with a neural network model to generate a physics-informed neural network (PINN) model associated with the downhole operation in the geological region.

In some embodiments, a computer-readable storage medium stores computer-executable instructions that, when executed by a processing system, are configured to cause the processing system to process a request to predict one or more parameters associated with a geological region, access a physics-based model associated with performing a downhole operation in the geological region, and integrate the physics-based model with a neural network model to generate a physics-informed neural network (PINN) model associated with the downhole operation in the geological region.

The brief summary presented above is intended only to familiarize the reader with certain aspects and contexts of embodiments of the present disclosure. This summary is not intended to identify key or essential features of the claimed subject matter, nor is it intended to be used as an aid in determining or limiting the scope of the claimed subject matter as set forth in the claims.

### BRIEF DESCRIPTION OF THE DRAWINGS

The present disclosure is further described in the following detailed description, and the accompanying drawings and schematics of non-limiting embodiments of the present disclosure. The features depicted in the figures are not necessarily shown to scale. Certain features of the embodiments may be shown exaggerated in scale or in somewhat schematic form, and some details of elements may not be shown in the interest of clarity and conciseness. These and other features, aspects, and advantages of the present disclosure will become better understood when the following detailed description is read with reference to the accompanying drawings in which like characters represent like parts throughout the drawings, wherein:

FIG. 1 is a schematic view of a wireline system including a downhole tool string, in accordance with aspects of the present disclosure;

FIG. 2 is a block diagram of certain force components acting on a downhole tool string of a wireline system, in accordance with aspects of the present disclosure;

FIG. 3 is a flowchart of a method for integrating a physics-based model with a multilayer perceptron (MLP) neural network model to generate a physics-informed neural network (PINN) model, in accordance with aspects of the present disclosure;

FIG. 4 is a flowchart of a method for adjusting wireline conveyance operations based on a PINN model and updating the PINN model based on feedback data associated with modified wireline conveyance operations, in accordance with aspects of the present disclosure;

FIG. 5 is a graph illustrating various surface tension measurements determined with default parameters, in accordance with aspects of the present disclosure; and

FIG. 6 is a graph illustrating various surface tension measurements determined with a PINN model, in accordance with aspects of the present disclosure.

### DETAILED DESCRIPTION

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, “coupled”, “connected”, and the like indicate establishing either a direct or indirect connection (e.g., where the connection may not include or include intermediate or intervening components between those coupled), and is not limited to either unless expressly referenced as such. The term “set” may refer to one or more items. Wherever possible, like or identical reference numerals are used in the figures to identify common or the same elements. To provide an understanding of how some embodiments of the present disclosure may be practiced, some figures may be described and reference components of other figures; however, it will appreciated that such components are illustrative and that methods or systems may include or be practiced using other components other than those specifically illustrated.

As used herein, “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. As used herein, the term “may” is employed to describe certain embodiments in which a component, feature, structure, or step is included in a described embodiment, but that such component, feature, structure, or step is optional and is not necessarily included in each embodiment within the scope of the present disclosure.

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Certain terms are used throughout the description and claims to refer to particular features or components. As one skilled in the art will appreciate, different persons may refer to the same feature or component by different names. This document does not intend to distinguish between components or features that differ in name, but not function.

In the oil and gas industry, a wireline conveyance model may be employed to perform various operations at a wellsite including well logging, maintenance, intervention, abandonment, perforation, and the like. The operations performed by the wireline conveyance help ensure asset integrity, production optimization, efficient reservoir management, and the like. To perform the wireline conveyance operations, a downhole tool string may be provided into a well or borehole via a cable using a winch system. The downhole tool string may be positioned in certain locations within the well to perform certain tasks such as logging, perforating, setting plugs, and the like. As such, accurately estimating the interaction between the tool string, the cable, the borehole, and the well may be helpful for determining wireline conveyance selections, operational designs, and risk evaluations.

In some embodiments, physics-based models may be used to estimate various methods or techniques for performing the wireline conveyance operations. However, physics-based models may suffer from inaccuracies due to complications and uncertain parameters (e.g., friction coefficients). Since accurate predictions from physics-based models are useful in efficiently performing wireline conveyance operations, the present embodiments described herein better enable physics-based models to account for various uncertainties in input parameters, such as friction coefficients.

In certain embodiments, a computing system may generate a wireline conveyance model that integrates a neural network with a physics-based model to improve prediction accuracy of various parameters and optimize wireline conveyance operations in real-time and planning phases. The physics-based model may represent a collection of laws of physics or nature that correspond to expected physical (e.g., motion) properties of objects. In some embodiments, the wireline conveyance model may integrate a multilayer perceptron (MLP) neural network with the physics-based model to form a physics-informed neural network (PINN) model. The MLP neural network may correspond to a particular type of neural network that is a feedforward model that outputs a prediction based on hidden layers that may perform mathematical transformations to input data to identify various patterns. By applying the physics-based model to the MLP neural network, present embodiments may generate the PINN model, which incorporates a neural network that integrates physical laws directly into its training process.

The physical laws may be provided by the physics-based model and may be expressed by partial differential equations. With this in mind, the physics-based model may act as a physical constraint and input into the PINN model by providing the MLP neural network with reference to certain laws of physics associated with the wireline conveyance operations. That is, the PINN model may simulate wireline conveyance operations in any suitable well trajectory by accounting for physics properties, such as gravity, buoyancy, friction, hydrodynamic forces, centralizer drag, tractor forces acting on a tool string or cable, and the like.

After receiving or otherwise accessing the physics-based model for the wireline conveyance operation, the computing system may integrate the physics-based model with the MLP neural network to generate the PINN model. That is, a parameter (e.g., surface tension, head tension, open-hole sticking probability, conveyance time, temperature gradient effects, pressure gradient effects, etc.) that may be predicted for a wireline conveyance operation of a well according to the physics-based model may serve as an input to the MLP neural network. The error between the parameter predictions and corresponding parameter measurements (e.g., historical data) may then be used to train the PINN model according to a residual modeling approach. As a result, the MLP neural network may provide an efficient and stable training framework for generating the PINN model using predictions provided by the physics-based model.

In some embodiments, the PINN model may also leverage relevant historical data from previous wireline conveyance jobs to enhance accurate prediction of parameters that are typically estimated in the physics-based model. The historical data may be associated with different geological locations covering various cables, tool strings, well geometries, winch speeds, conveyance methods, and the like. The PINN model may be tuned to predict certain parameters, such as surface tension, head tension, open-hole sticking probability, conveyance time, the effects of temperature and pressure gradients, and the like. The fusion of the physical simulation of the parameters based on the physics-based model and the historical data improves prediction accuracy in output parameters and increases tolerances in input uncertainties. Additionally, the historical data may be used to validate the prediction accuracy of the PINN model and further train the PINN model.

By performing the embodiments described herein, the computing system may generate the PINN model for simulating wireline conveyance operations by combining historical data (e.g., measured or observed data) and the physics-based model (e.g., outputting predicted data) to enhance accurate prediction various uncertain inputs. Indeed, in some embodiments, the computing system may accurately predict output parameters using just the physics-based model when historical data may not be available for training purposes. However, by incorporating the historical data into the training of the PINN model, the resulting PINN model may reduce its dependency on uncertain inputs that may be estimated in the physics-based model. In any case, the PINN model generated in accordance with embodiments described herein may have improved accuracy and may offer a competitive advantage by enhancing design and execution, leading to at least one of faster conveyance, reduced anomalies, or accurate risk estimation. The PINN model's adaptability to various job configurations and its ability to simulate a range of wireline conveyance scenarios may also enable broader application through precise tuning across diverse basins.

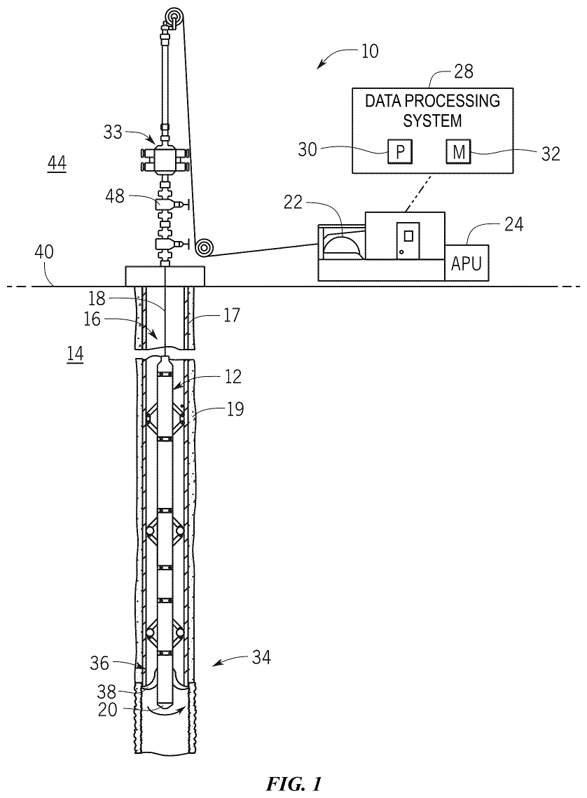

By way of introduction, FIG. 1 illustrates a wireline system 10 that may employ the systems and methods of this disclosure. The wireline system 10 may be used to convey a downhole tool string 12 through a geological formation 14 via a wellbore 16 (e.g., completed wellbore) to perform various operations such as well logging, maintenance, interventions, perforation, and the like. In some embodiments, a casing 17 may be positioned within the wellbore 16, such that the downhole tool string 12 may traverse the wellbore 16 within the casing 17. As discussed in detail below, a cement lining 19 may be positioned between the casing 17 and the geological formation 14, such that the casing 17 is cemented (e.g., affixed to) the surrounding geological formation 14. For clarity, as used herein, the casing 17 and the cement lining 19 may be referred to as respective “features” of the wellbore 16.

The downhole tool string 12 may be conveyed through the wellbore 16 via a cable 18 of the wireline system 10. The wireline system 10 may be substantially fixed (e.g., a long-term installation that is substantially permanent or modular) or may be a mobile wireline system, such as a wireline system carried by a truck. Any suitable cable 18 may be used to convey the downhole tool string 12 through the wellbore 16. The cable 18 may be spooled and unspooled on a drum 22 of the wireline system 10. In some embodiments, a power unit 24 may provide energy (e.g., electrical energy) to the wireline system 10 and/or the downhole tool string 12.

The wireline system 10 may include a data processing system 28 that may control operations of the wireline system 10 and/or the downhole tool string 12 in accordance with techniques discussed herein. In some embodiments, the data processing system 28 enables autonomous operation of the downhole tool string 12 within the wellbore 16. Further, as discussed in detail below, the data processing system 28 may predict certain parameters for the wireline conveyance operation using a physics-informed neural network (PINN) model. The predicted parameters may be used during wireline conveyance operations, including to make adjustments to the wireline conveyance operations. To perform these tasks, the data processing system 28 may include a processor 30, which may execute instructions stored in a memory 32. As such, the memory 32 may be any suitable article of manufacture that can store the instructions. The memory 32 and may be read-only memory (ROM), random-access memory (RAM), flash memory, an optical storage medium, or a hard disk drive, to name a few examples.

In the illustrated embodiment, the wireline system 10 includes wellbore equipment or pressure control equipment 33 at or near a surface 40 of the geological formation 14. The pressure control equipment 33 enables the cable 18 to move the downhole tool string 12 through the wellbore 16, while substantially blocking pressurized fluid within the wellbore 16 from leaking into an ambient environment 44 (e.g., the atmosphere). In some embodiments, the pressure control equipment 33 includes a pack-off 48 that may form a fluidic seal around the cable 18. For example, the cable 18 may pass through an annular opening within the pack-off 48 that may conform to an external surface of the cable 18, thus forming the fluid seal. Accordingly, the pack-off 48 may mitigate wellbore fluids or other contaminants, such as grease, from entering the wellbore 16 or discharging from the wellbore 16. It should be appreciated that the pressure control equipment 33 may include any other suitable components or combination of components that may facilitate traversing the cable 18 and the downhole tool string 12 through the wellbore 16. That is, the pressure control equipment 33 may additionally or alternatively include, for example, a lubricator, a tool trap, a pump-in-sub, a cable shearing device, multiple motorized rollers, or any other suitable component(s).

In the illustrated embodiment, the wireline system 10 includes a bottom hole assembly (BHA) 34. The BHA 34 may include a drill bit 20 and a reamer section 36 (e.g., expandable reamer portion). The reamer section 36 includes one or more reamers 38 (e.g., reamer arms, cutting arms) rotatably coupled to the reamer section 36. The reamers 38 of the reamer section 36 may extend in a radial outward direction from a radially retracted configuration to a radially expanded configuration to increase a cutting diameter, and also retract in a radially inward direction from the radially expanded configuration to the radially retracted configuration to reduce the cutting diameter. For example, in certain embodiments, the data processing system 28 may actively control actuation of the reamers 38 from the radially retracted configuration to the radially expanded configuration, while the reamers 38 may passively move from the radially expanded configuration to the radially retracted configuration. In other embodiments, other downhole tools may be included in the BHA 34 in addition to, or instead of, reamers 38 and/or drill bit 20. Examples of other tools include, by way of illustration, calipers, fluid injectors, fluid testing equipment, stimulation tools, perforation tools, milling or casing cutting tools, debris collectors, filters, downhole motors, or other tools usable in wireline or slickline operations.

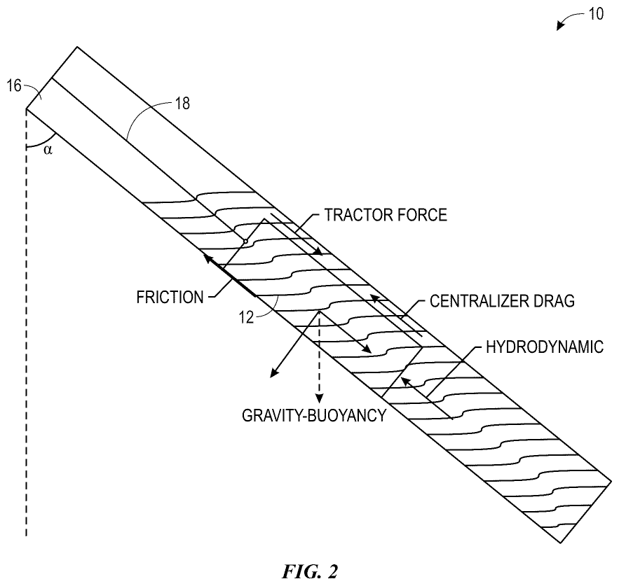

FIG. 2 is a block diagram illustrating certain force components that may be acting on the downhole tool string 12. In some embodiments, a computing system or controller (e.g., data processing system 28 of FIG. 1) may employ a physics-based model to simulate various methods or techniques that may be performed by the wireline system 10 to predict the behavior and stability of the downhole tool string 12 as the downhole tool string 12 travels through the wellbore 16. The certain force components may include gravity, buoyancy, friction, hydrodynamic forces, centralizer drag, tractor forces, and the like.

The certain force components may be utilized to simulate certain wireline conveyance operations using a physics-based model. The certain force components may include static parameters and/or timeseries parameters. The static parameters may be parameters that stay constant throughout the wireline conveyance operation. The static parameters may include cable properties, downhole tool string properties, cable and downhole tool string geometry, and the like that remain constant throughout the wireline conveyance operation. The timeseries parameters may capture the progression of the wireline conveyance operation at various positions as the downhole tool string 12 travel through wellbore 16. Example timeseries parameters include cable length, winch speed, tractor force, pumping rate, and other parameters that vary during the wireline conveyance operation. The static parameters may include certain observed parameters and certain estimated parameters. The observed parameters may be obtained through direct measurement; however, the estimated parameters may be determined using models, historical information, and other estimation techniques. As such, the estimated parameters (e.g., surface tension, head tension, open-hole sticking probability, conveyance time, the effects of temperature and pressure gradients) may not fully reflect the wireline conveyance operation's condition even when based on a physics-based model. The predicted physics-based parameters may predict the behavior and stability of the downhole tool string 12 during wireline conveyance operations.

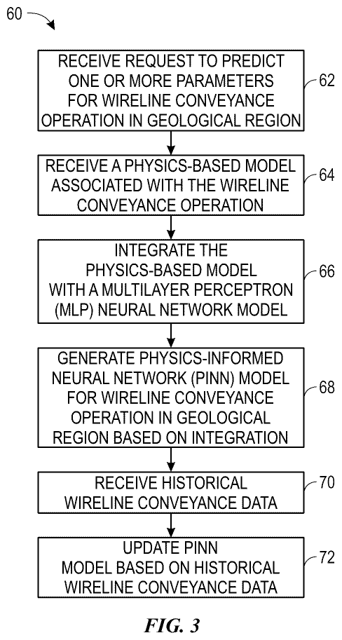

With the forgoing in mind, FIG. 3 is a flowchart illustrating a method 60 of integrating the physics-based model with the multilayer perceptron (MLP) neural network model to generate the physics-informed neural network (PINN) model. Although the following description of the method 60 is described as being performed by the data processing system 28 (see FIG. 1), it should be noted that the method 60 may be performed by any suitable computing system and in any suitable order.

Referring now to FIG. 3, at block 62, the data processing system 28 may generate, receive, or otherwise access a request to predict certain parameters for a wireline conveyance operation in a geological formation. The parameters may include a variety of properties, such as surface tension, head tension, open-hole sticking probability, conveyance time, the effects of temperature and pressure gradients, and the like. The parameters may be used to predict the behavior and stability of a downhole tool string (e.g., downhole tool string 12 of FIG. 1 or 2) as the downhole tool string 12 travels through the well 16 during the wireline conveyance operation. In some embodiments, the data processing system 28 may utilize the predicted parameters to mitigate operational risks, such as preventing cable breakage/damage or downhole tool string loss, to determine the feasibility of the downhole tool string reaching the total depth of the well, to determine efficient run-in-hole (RIH) and pull-out-of-hole (POOH) speeds, and the like.

At block 64, the data processing system 28 may receive or otherwise access a physics-based model associated with the wireline conveyance operation and the parameters received at block 62. The physics-based model may be stored in a database or some other suitable storage component and may be retrieved by the data processing system 28 based on the type of wireline conveyance operation being performed, properties (e.g., shape of wellbore, type of geologic formation) related to the wireline system, and the like. As mentioned above, the physics-based model may represent a collection of laws of physics or nature that correspond to expected physical (e.g., motion) properties of objects that may be part of the wireline system and/or the corresponding geological formation. In the method 60, the data processing system 28 may use the physics-based model to predict certain parameters that provide insight into the expected behavior of the downhole tool string 12 and cable 18 during the wireline conveyance operations. Based on the predicted parameters from the physics-based model, the data processing system 28 may send commands to devices of the wireline conveyance system 10 to adjust settings, such as the winch speed, downhole tool string speed, wireline tension, power, tool position, and the like. As such, the parameters predicted by the physics-based model may adjust the wireline conveyance operations in real-time and in planning phases. However, the parameters predicted by the physics-based model may suffer from inaccuracies due to complex downhole interactions or complication with the wireline conveyance operation and uncertain parameters (e.g., friction coefficients) utilized to calculate mathematically the certain predicted parameters.

With this in mind, at block 66, the method 60 may include the data processing system 28 integrating the physics-based model with a multilayer perceptron (MLP) neural network model. In some embodiments, the data processing system 28 may utilize the certain predicted parameters from the physics-based model as a feature or input to the MLP neural network. The MLP neural network may be a feed-forward model that outputs a prediction based on hidden layers that may perform mathematical transformations to an input feature vector to identify various patterns of the wireline conveyance operation.

The MLP neural network may include an input layer, multiple hidden layers, an output layer, other layers, or some combination thereof. The input layer may take the input feature vector where the input feature vector may be an array of certain observed parameters, and where the certain observed parameters may include static features and timeseries features from the physics-based model. That is, the input feature vector may exclude the estimated parameters utilized for the physics-based model. The static features used in the input layer may include datasets that largely remain the same, such as the downhole tool string mass, the downhole tool string volume, the cable mass per unit length in air, and the like. The timeseries features used in the input layer may include datasets that vary between operations, such as cumulative well curvature to the current depth, max well curvature to the current depth, well curvature standard deviation to the current depth, and the like. In some cases, the timeseries features may also include datasets related to predicted parameters obtained from the physics-based model at various times and depths during a simulated downhole tool operation. In some embodiments, the input layer may have one neuron for each observed parameter of the input feature vector and each neuron may be basic building blocks used for the MLP neural network. However, it should be noted that the input layer may be implemented in a number of different manners. For instance, the input layer may include one neuron for each value of a vector rather than for the entire vector.

The hidden layers may be layers where the MLP neural network may learn patterns of the wireline conveyance operation to generate accurate predictions. That is, the data processing system 28 may utilize the predicted parameters from the physics-based model as inputs for a residual modeling approach by setting the error between the predicted parameters from the physics-based model and the corresponding parameter measurements (e.g., historical data of the wireline conveyance operation) used to train the MLP neural network. Equation (1), as stated below, may determine the error based on a residual modeling approach.

$${\overline{y}}_{r esidual}^{past} = {\overline{y}}_{parameters}^{past} - {\overline{y}}_{physics}^{past} \qquad ( 1 )$$

### In Equation (1),

$${\overline{y}}_{r esidual}^{past}$$

may represent the vector of residual learning patterns for the hidden layers,

$${\overline{y}}_{parameters}^{past}$$

may represent the vector of corresponding parameter measurements, and

$${\overline{y}}_{physics}^{past}$$

may represent the vector of parameters predicted from the physics-based model.

In some embodiments, the MLP neural network may include multiple hidden layers. For instance, in a particular embodiment, there may be three hidden layers where the first two hidden layers may have the same number of neurons as the input layer, and the third hidden layer may have fewer neurons as the MLP neural network may correspond to the MLP neural network gradually compressing the information from the patterns. The MLP neural network may utilize Equation (2), as stated below, where Equation (2) describes how values may be calculated in the hidden layers. That is, Equation (2) may be a rectified linear unit (ReLU) activation used to learn the residual learning patterns of the MLP neural network, where the activation function may output a zero if the residual is a zero or a negative and output the same value if the residual is positive.

$${a}^{l} = max ( 0 , {\overline{W}}^{l} {a}^{l - 1} + {\overline{b}}^{l} ) \qquad ( 2 )$$

In Equation (2), l may denote the layer number, where the input layer may be denoted as l=0 and the output layer may be denoted as l=4 and where a′ may be the output vector from the l^{th} layer, in which a⁰ may be the input feature vector, W̅^{l} may be the weight matrix, and b̅^{l} may be the bias vector in the l^{th} layer. As such, the residual learning patterns may implicitly account for the estimated parameters excluded from input feature vector when generating the final predicted residual.

The data processing system 28 may determine the output layer of the MLP neural network where the output layer may be a single neuron, and where the output layer may produce a final predicted residual. The MLP neural network may utilize Equation (3) to determine the final predicted residual,

$${\overline{y}}_{residual}^{new} ,$$

predicted residual may be the residual between the predicted parameter and the predicted parameter of the physics-based model.

$${\overline{y}}_{r esidual}^{new} = {\overline{W}}^{4} {a}^{3} + {\overline{b}}^{4} \qquad ( 3 )$$

The MLP neural network may provide an efficient and stable training setup with an Adam optimizer and a mean squared error (MSE) as a loss function. The loss function may determine the discrepancy between a predicted residual and certain residual learning patterns. The MLP neural network may utilize the Adam optimizer to minimize the loss function between the predicted residual and the residual learning patterns. The MLP neural network may continue through multiple iterations until the loss function reaches a minimum possible value (e.g., changes between errors are less than a threshold), where the end result is the final predicted residual.

In some embodiments, the PINN model may be trained by lowering the loss function in the MLP neural network. The data processing system 28 may employ an early stopping mechanism when there is no improvement detected in lowering the loss function.

With continued reference to FIG. 3, at block 68, the data processing system 28 may generate a physics-informed neural network (PINN) model for the wireline conveyance operation in the geological region based on the integration performed at block 66. That is, the data processing system 28 may utilize the final predicted residual to determine the predicted parameter for the PINN model. Optionally, the predicted parameter is determined by Equation (4), as stated below.

$${\overline{y}}_{parameter}^{new} = {\overline{y}}_{physics}^{new} + {\overline{y}}_{r esidual}^{new} \qquad ( 4 )$$

In this equation,

$${\overline{y}}_{physics}^{new}$$

represent the predicted parameter of the physics-based model and

$${\overline{y}}_{parameter}^{n e w}$$

represents the PINN-predicted parameter of the wireline conveyance operation. The PINN-predicted parameter represents the parameter when the wireline conveyance operation is at a specific position within the wellbore 16. As the downhole tool string 12 moves through the wellbore 16, the new position of the wireline conveyance operation may generate a new input feature vector. The new input feature vector may include the predicted parameter from the physics-based model at the new position. In some embodiments, the PINN-predicted parameter may be utilized in the MLP neural network to generate a new PINN-predicted parameter for the new position as the corresponding measurements.

At block 70, the data processing system may receive or otherwise access historical wireline conveyance data. The historical wireline conveyance data may include data from previous wireline conveyance operations such as the static parameters, the timeseries parameters, the estimated parameters generated by the physics-based model, the error between the estimated parameters generated by the physics-based model and the actual parameters of the wireline conveyance operations, the geological classification at the wireline conveyance operation, and the like.

At block 72, the data processing system may update the PINN model based on the historical wireline conveyance data. The PINN model may generate the PINN-predicted parameter with the historical wireline conveyance data by utilizing the estimated parameters. However, in some embodiments, the PINN model may utilize the historical wireline conveyance data to train the PINN model to align the PINN model predictions with the historical wireline conveyance data. That is, in the method 60, the data processing system 28 may utilize the historical wireline conveyance data to train the MLP neural network of the PINN model. This is optionally performed by setting the error between the predicted parameters from the physics-based model and the corresponding parameter measurements from the historical wireline conveyance data using Equation (1).

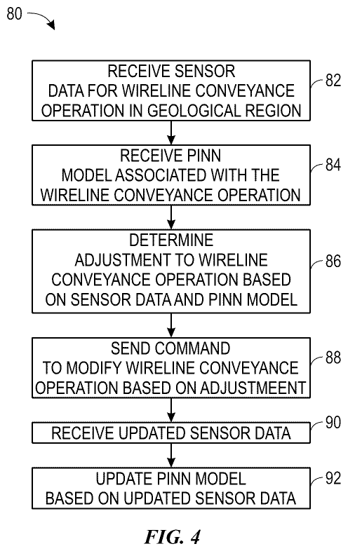

FIG. 4 is a flowchart of a method 80 for adjusting wireline conveyance operations based on the PINN model and updating the PINN model based on feedback data associated with modified wireline conveyance operations. Although the method 80 is described as being performed by the data processing system 28 of FIG. 1 and in a particular order, it should be understood that the method 80 may be performed by any suitable computing system and in any suitable order.

At block 82, the data processing system 28 may receive sensor data for the wireline conveyance operation in the geological formation. The sensor data may include the static parameters and/or timeseries parameters as the downhole tool string 12 (see FIGS. 1 and 2) travels through the wellbore 16. The sensor data may be associated with the position of the downhole tool string 12 in the wellbore 16.

At block 84, the data processing system 28 may receive or otherwise access the PINN model associated with the wireline conveyance operation. The data processing system 28 may utilize the PINN model to determine the PINN-predicted parameter at the current position of the downhole tool string 12 in the wellbore 16.

At block 86, the method 80 may use the data processing system 28 and/or downhole tool string 12 to determine adjustments for the wireline conveyance operation based on the sensor data and the PINN model. That is based on the PINN-predicted parameters from the PINN model and the sensor data from the wireline conveyance operation, the data processing system 28 may determine the interaction between the downhole tool string 12, cable 18, and wellbore 16 accurately as the downhole tool string 12 moves down the wellbore 16 for a wireline conveyance operation. For instance, if the current trajectory of the downhole tool string 12 is projected to cause tension during the wireline conveyance operation, for example during RIH and POOH operations, the data processing system 28 may adjust the trajectory of the downhole tool string 12 in the wellbore 16. In some embodiments, the data processing system 28 may be partially included in the downhole tool string 12. Accordingly, determining adjustments for the wireline conveyance operation may be performed at the surface, downhole, or a combination thereof.

At block 88, the data processing system 28 may send or generate a command to modify the wireline conveyance operation based on the adjustments. As such, a controller, for example, may receive the commands associated with the wireline conveyance operation adjustments and adjust the downhole tool string 12 accordingly. The controller may perform various actions to adjust the downhole tool string 12, such as the winch speed, the hydraulic force, and the like. In some embodiments, the controller may operate as the data processing system 28 that performs the method 80 or portions thereof. In other embodiments, the controller may be part of the downhole tool string 12. In still other embodiments, the controller may be separate from, but coupled to, the data processing system 28 and/or the downhole tool string 12.

At block 90, the data processing system 28 may receive updated sensor data. The updated sensor data may be sensor data associated with the downhole tool string 12 at a new position or condition in the wellbore 16. That is, as the downhole tool string 12 moves through, or performs operations within, the wellbore 16, new sensor data may be collected at each new position or different operation of the downhole tool string 12.

At block 92, the data processing system 28 may update the PINN model based on the updated sensor data. The PINN model may be updated by adjusting the input parameters of the MLP neural network to predict the parameters at the new position of the downhole tool string 12. As such, the data processing system 28 may continue to perform the method of 80 as the downhole tool string 12 moves through or otherwise performs operations within the wellbore 16 to adjust the downhole tool string 12.

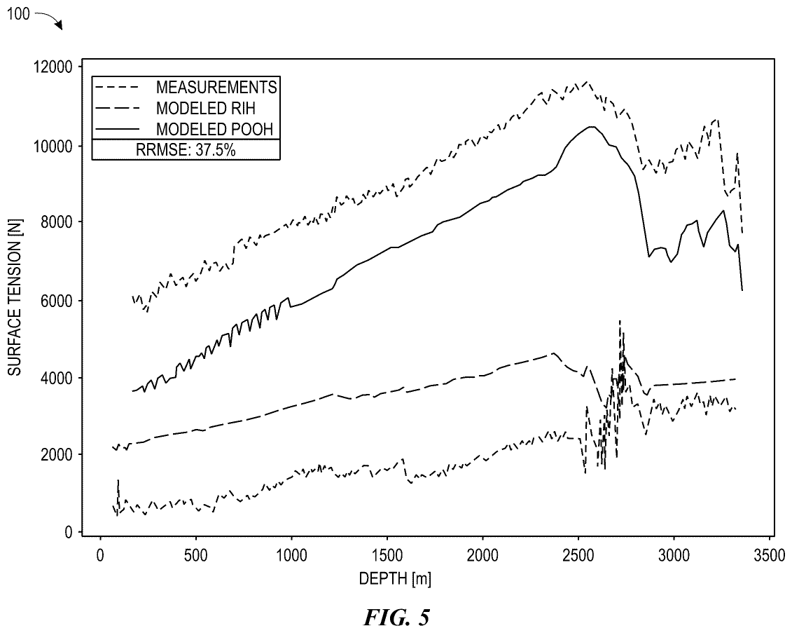

FIG. 5 is a graph illustrating various surface tension measurements determined with default parameters. In the particular embodiment illustrated in FIG. 5, the default parameters graph 100 illustrates the relative root mean square error (RRMSE) of the predicted parameter from the physics-based model versus the measured parameter from the wireline conveyance operation. For example, the physics-based model may predict the surface tension of the wireline conveyance operation. The predicted surface tension (e.g., modeled RIH, modeled POOH) may then be compared to the measured surface tension (dashed line) from the wireline conveyance operation using Equation (5)

$$RRMSE = \frac{\sqrt{\frac{1}{N} {\sum }_{i = 1}^{N} {( {m}_{par {ameter}^{i}}^{target} - {y}_{par {ameter}^{i}}^{target} )}^{2}}}{\frac{1}{N} {\sum }_{i = 1}^{N} {m}_{par {ameter}^{i}}^{target}} \qquad ( 5 )$$

### In Equation (5),

$${m}_{par {ameter}^{i}}^{target}$$

may represent the measured parameter at the i^{th} timestep of the wireline conveyance operation,

$${y}_{par {ameter}^{i}}^{target}$$

may represent the predicted parameter of the physics-based model at the i^{th} timestep of the wireline conveyance operation, and N may represent the total number of timesteps in the wireline conveyance model. In this example, the surface tension may be the parameter measured and predicted. The RRMSE between the predicted surface tension and the measured surface tension is notably high due to the estimated parameters required to generate the precited surface tension using the physics-based model.

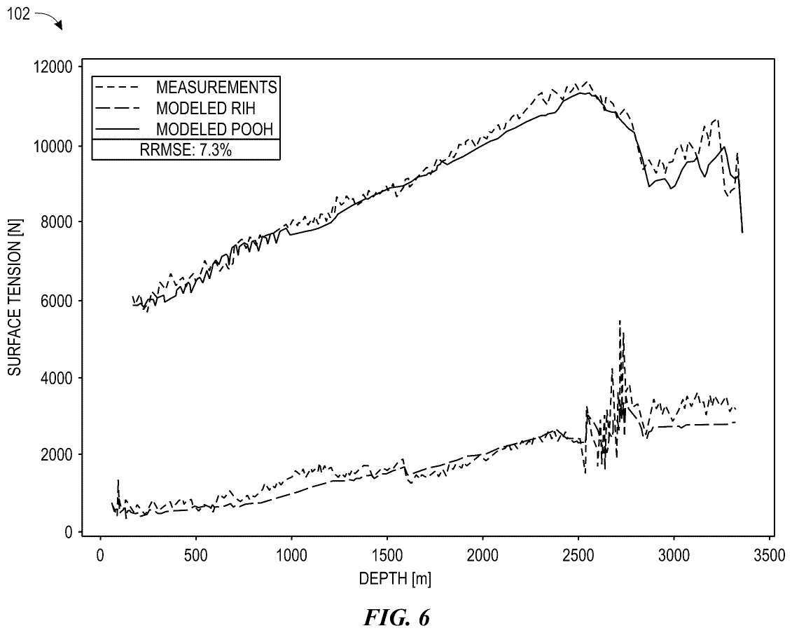

In comparison, the graph in FIG. 6 illustrates various surface tension measurements determined with the PINN model. That is, the PINN model graph 102 may illustrate the RRMSE of the PINN-predicted parameter versus the measured parameter from the wireline conveyance operation. For example, the PINN-predicted parameter may predict the surface tension of the wireline conveyance operation. The PINN-predicted surface tension (solid and long-dashed line) may be compared to the measured surface tension (dashed line) from the wireline conveyance operation using Equation (5) above. To produce the graph in FIG. 6,

$${m}_{par {ameter}^{i}}^{target}$$

may represent the measured parameter at the i^{th} timestep of the wireline conveyance operation,

$${y}_{par {ameter}^{i}}^{target}$$

may represent the PINN-predicted parameter at the i^{th} timestep of the wireline conveyance operation, and N may represent the total number of timesteps in the wireline conveyance model. In this example, the surface tension may be the parameter measured and predicted. Compared to FIG. 5, the RRMSE between the PINN-predicted surface tension and the measured surface tension is notably lower, showing higher prediction accuracy due to the MLP neural network in the PINN model.

Further, by performing the embodiment described above, the PINN model may utilize a residual-learning model that may use a full mechanistic simulator. The mechanistic simulator may be specialized for a multi-physics wireline conveyance (e.g., mechanics, hydraulics, friction, and the like). In some embodiments, the inputs for the MLP neural network do not include estimated parameters such as friction factors, mud viscosity, centralizer drag, and the like. Rather, the MLP neural network may implicitly learn the estimated parameters through the residuals. Thus, the PINN model may remove the inaccuracies the physics-based model has when generating the predicted parameters. The PINN model may treat each timestep of a timeseries independently that may summarize the trajectory metrics. By summarizing the future trajectory measurements, the PINN model may provide real-time updates, along with training the MLP neural network with limited historical data of wireline conveyance operations.

In addition, the embodiments described above provide for a hybrid wireline conveyance prediction system that may include a physics-based cable/tool mechanics simulator, as well as a neural network that may be trained to model a residual error between physics predictions and measured surface tension values. An input feature vector may include just observed physical parameters and geometry descriptors, including statistical curvature features the physics-model output. The hybrid wireline conveyance prediction system may be used to estimate a final tension estimate as physics prediction with a neural network residual. As a result, the present embodiments allow for accurate predictions to be made using minimal data, including a single historical run. Moreover, the present embodiments allow for the removal of uncertain parameters (e.g., friction coefficients, mud properties) from the model input to provide improved robustness across widely varying tool strings and geometries. real-time adaptability and compatibility with automation, superior accuracy to parameter-tuned physics models, and the like.

In addition to the context provided above, in some embodiments, a hybrid wireline conveyance prediction system (e.g., implemented via the data processing system 28) can be built to combine a physics-based “mechanistic” simulator with a machine learning model (e.g., neural network) to correct residual errors in the output of a simulator. Such physics-based simulators may compute a predicted surface and/or head cable tension(s) based on observed physical parameters and mechanistic modeling of cable and toolstring behavior in a wellbore. The mechanistic modeling may include gravity, buoyancy, hydrodynamic drag, capstan effects (effect of curvature), centralizer drag, tractor forces, winch speed, and other properties associated with equipment performing the wireline conveyance. The machine learning model or neural network may be trained to predict absolute surface tension and a residual value, such that the final tension estimate may be computed as the sum of physics-predicted tension and the residual predicted by the neural network.

In some embodiments, the neural network may receive (e.g., as input) a feature vector that may include observed or reliably measured parameters and a set of derived engineered descriptors. The inputs may include static parameters (e.g., mass of toolstring components, volume, and geometric sizing of individual assets); trajectory-based curvature descriptors (can be extracted from the well survey e.g.); dynamic operational parameters such as cable speed, cable length, flow rate, and tractor force; and the physics-predicted tension itself. It should be noted that the feature vector may be designed to explicitly exclude some estimated parameters or factors such as friction coefficients, mud viscosity, mud density, centralizer drag coefficients, and friction in surface equipment due to the uncertainty in the accuracy of their respective values. Based on the insight provided using a mechanistic simulator's residual error, the neural network may implicitly capture effects of uncertain parameters without having them as used as explicit inputs. As a result, the present embodiments may reduce sensitivity to misspecification of parameters and can enable a reliable operation even with limited training data.

In another example, the present embodiments described herein may be employed to perform real-time wireline tension prediction during conveyance. In this example the hybrid prediction system (e.g., implemented via the data processing system 28) may be deployed during a live wireline conveyance operation. As such, surface equipment may measure parameters, such as cable tension, cable speed, deployed cable length, and the like at successive timesteps. A physics-based conveyance simulator may then discretize the well trajectory into segments that may be defined by inclination and azimuth and may then compute a physics-predicted surface tension by propagating forces, such as gravity, buoyancy, drag, curvature-induced capstan effects, and the like, from the toolstring to the surface. The neural network may then receive (e.g., at each timestep) observed operational parameters, derived curvature information obtained from a well survey, physics-predicted surface tension, and the like. The neural network may produce a residual correction to be combined with the physics-based prediction to yield the corrected surface tension estimate. Such estimate may be used in real time to alarm an operator or a computer automation system about anomalies when a deviation between predicted and measured tension exceeds some threshold, such that a computing system may modify operational parameters, such as winch speed, applied tractor force, or other parameter associated with the equipment performing the wireline conveyance.

In another example, the present embodiments may perform direct physics-guided/informed tension prediction using limited historical field datasets. In this embodiment, a physics-informed neural network (PINN) maybe trained to directly predict surface cable tension using data from a limited number of prior wireline runs. Each training sample may correspond to a timestep and may include observed operational parameters, engineered geometric descriptors derived from the well trajectory, outputs of a physics-based conveyance simulator, and the like. During a wireline operation, the trained neural network may receive real-time inputs, such as cable speed, deployed cable length, curvature-based info, physics-model outputs for any current timestep, outputs a predicted surface tension, and the like. The prediction may incorporate both “mechanistic” behavior and “learned” deviations from idealized physics and may be used to monitor operational safety limits, catch anomalies, support automation system control actions, and the like by adjusting winch speed and/or tractor force of equipment performing the wireline conveyance. The PINN may leverage physics-model outputs as its inputs to achieve a reliable performance with minimal historical field dataset without the use or inclusion of certain uncertain parameters (e.g. friction coefficients or mud properties).

Embodiments of the present disclosure may include or be performed by a special-purpose or general-purpose computing system (e.g., data processing system 28) that includes computer hardware, such as one or more processors 30 and system memory 32. Embodiments within the scope of the present disclosure also include physical and other computer-readable media for carrying or storing computer-executable instructions and/or data structures. Such computer-readable media can be any available media that can be accessed by a computing system. Computer-readable media that store computer-executable instructions and/or data structures are computer-readable storage media. Computer-readable media that carry computer-executable instructions and/or data structures are computer-readable transmission media. Thus, by way of example and not limitation, embodiments of the present disclosure can include at least two distinctly different kinds of computer-readable media, namely computer-readable storage media and computer-readable transmission media.

Computer-readable storage media is physical storage media that store computer-executable instructions and/or data structures. Computer-readable storage media includes physical computer hardware, such as RAM, ROM, EEPROM, solid state drives (“SSDs”), flash memory, phase-change memory (“PCM”), optical disk storage, magnetic storage devices, or any other hardware storage device which can be used to store instructions or data in the form of computer-executable instructions or data structures, and which can be accessed and executed by a computing system to implement the disclosed functionality.

Computer-readable transmission media is a network and/or data link which can be used to carry computer-executable instructions or data structures, and which can be accessed by a computing system. A network includes one or more data links that enable the transport of electronic data between computing systems, modules, or other electronic devices. When information is transferred or provided over a network or another communications connection (either hardwired, wireless, or a combination of hardwired or wireless) to a computing system, the computing system may view the connection as computer-readable transmission media.

Combinations of computer-readable storage media and computer-readable transmission media are also within the scope of computer-readable media. Further, computer-executable instructions or data structures can be transferred automatically from computer-readable transmission media to computer-readable storage media, or vice versa. For example, computer-executable instructions or data structures received over a network or data link can be buffered in RAM within a network interface module and thereafter transferred to less volatile computer-readable storage media on or accessible to the computing system. Thus, it should be understood that computer-readable storage media can be included in a computing system that also utilizes computer-readable transmission media.

The subject matter described in detail above may be defined by one or more clauses, as set forth below.

A method includes accessing or generating a request to predict one or more parameters associated with a geological region, accessing a physics-based model associated with performing a downhole operation of the geological region, and integrating the physics-based model with a neural network model to generate a physics-informed neural network (PINN) model associated with the downhole operation in the geological region.

The method of the preceding clause, wherein the method is performed using at least one processing system.

The method of any preceding clause, wherein accessing or generating the request to predict one or more parameters associated with the geological region includes receiving the request.

The method of any preceding clause, wherein accessing the physics-based model associated with the downhole operation in the geological region includes receiving the physics-based model or accessing the physics-based model from a data structure.

The method of any preceding clause, wherein the downhole operation is a wireline operation.

The method of any preceding clause, wherein the neural network model includes a multilayer perceptron neural network model.

The method of any preceding clause, wherein integrating the physics-based model with the neural network model includes constraining the neural network model based on one or more properties associated with the physics-based model.

The method of any preceding clause, including accessing historical data associated with the downhole operation and/or the geological region, and updating the PINN model based on the historical data.

The method of any preceding clause, including generating one or more commands for downhole equipment associated with the downhole operation in the geological region based on the PINN model and sending the one or more commands to the downhole equipment, wherein the downhole equipment is configured to adjust downhole operation based on the one or more commands.

The method of the preceding clause, wherein the equipment is downhole equipment.

The method of any preceding clause, wherein the downhole equipment includes a wireline conveyance tool.

A system includes a computer-readable storage medium including one or more instructions and a processing system. The processing system is configured to execute the one or more instructions, with the one or more instructions causing the processing system to receive or otherwise access a request to predict one or more parameters associated with a geological region, receive or otherwise access a physics-based model associated with performing a downhole operation in the geological region, and integrate the physics-based model with a neural network model to generate a physics-informed neural network (PINN) model associated with the downhole operation in the geological region.

The system of the preceding clause, wherein the physics-based model is associated with performing a wireline operation within the geological region.

The system of any preceding clause, wherein the neural network model includes a multilayer perceptron neural network model.

The system of any preceding clause, integrating physics-based model with the neural network model includes constraining the neural network model based on one or more properties associated with the physics-based model.

The system of any preceding clause, wherein the processing system executing the one or more instructions causes the processing system to receive or otherwise access historical data associated with the downhole operation, geological region, or any combination thereof and update the PINN model based on the historical data.

The system of any preceding clause, wherein the processing system executing the one or more instructions causes the processing system to generate one or more commands for downhole equipment associated with the geological region based on the PINN model and to send the one or more commands to the downhole equipment, wherein the downhole equipment is configured to adjust the downhole operation based on the one or more commands.

The system of the preceding clause, wherein the downhole equipment includes a wireline conveyance tool.

A computer-readable storage medium including computer-executable instructions that, when executed by a processing system, are configured to cause the processing system to process a request to predict one or more parameters associated with a geological region, access a physics-based model associated with performing a downhole operation in the geological region, and integrate the physics-based model with a neural network model to generate a physics-informed neural network (PINN) model associated with the downhole operation in the geological region.

The computer-readable storage medium of the preceding clause, wherein the downhole operations is a wireline operation within the geological region.

The computer-readable storage medium of any preceding clause, wherein the neural network model includes a multilayer perceptron neural network model.

The computer-readable storage medium of any preceding clause, wherein integrating the physics-based model with the neural network model includes constraining the neural network model based on one or more properties associated with the physics-based model.

The computer-readable storage medium of any preceding clause, wherein the computer executable instructions, when executed by the processing system, are further configured to cause the processing system to access historical data associated with one or more of the downhole operation or the geological region and update the PINN model based on the historical data.

The computer-readable storage medium of any preceding clause, wherein the computer executable instructions, when executed by the processing system, are further configured to cause the processing system to generate one or more commands for downhole equipment associated with the geological region based on the PINN model and send the one or more commands to the downhole equipment, wherein the downhole equipment is configured to adjust the downhole operation based on the one or more commands.

A method for implementing a hybrid physics-guided residual learning system for wireline conveyance may include receiving, via a processing system, a request to predict one or more parameters associated with performing the wireline conveyance in a borehole within a geological region. Example parameters used in the method may be associated with the equipment performing the wireline conveyance and can include surface tension, head cable tension, or both. In the method, a physics-based model is accessed, with the physics-based model being associated with a mechanistic modeling of a cable and/or a toolstring performing the wireline conveyance for one or more downhole operations in the borehole in the geological region. The physics-based model may be generated based on one or more properties associated with the equipment. Such properties optionally include gravity, buoyancy, hydrodynamic drag, capstan effects (e.g., effect of curvature), centralizer drag, tractor forces, winch speed, or any combination thereof. The method may also involve integrating the physics-based model with a neural network model to generate a physics-informed neural network (PINN) model associated with performing the wireline conveyance in the geological region. The neural network may be trained to predict the one or more parameters (e.g., surface tension, head cable tension) based on a combination of any or each of the one or more properties, the wireline conveyance, or the downhole operation.

A method may include receiving, via a processing system, a request to predict one or more parameters associated with performing a wireline operation within a geological region. The one or more parameters may include surface tension, head tension, open-hole sticking probability, conveyance time, temperature gradient effects, pressure gradient effects, or any combination thereof. The method may also include receiving a physics-based model associated with performing the wireline operation within the geological region. The method may also include integrating the physics-based model with a multilayer perceptron neural network model by constraining the multilayer perceptron neural network model based on one or more properties associated with the physics-based model to generate a physics-informed neural network (PINN) model associated with performing the wireline operation in the geological region. The one or more properties may include expected physical properties of one or more objects part of a wireline conveyance tool performing the wireline operation within the geological region. The method may then involve generating one or more commands for the wireline conveyance tool associated with the wireline operation in the geological region based on the PINN model and sending the one or more commands to the wireline conveyance tool, wherein the wireline conveyance tool is configured to adjust the wireline operation based on the one or more commands

One or more computer-readable storage media including computer-executable instructions that, when executed by a processing system, cause the processing system to perform the method of the preceding clause.

A system including the one or more computer-readable storage media and the processing system of the preceding clause.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to explain the principals of the disclosure and its practical applications, to thereby enable persons skilled in the art to utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted as functional limitations not limited to a specific structure, but to cover all elements cable of performing the recited function. However, for any claims containing elements designated in any other manner, it is intended that such elements are not to be interpreted as functional limitations.

What is claimed is:

1. A method, comprising:
receiving, via a processing system, a request to predict one or more parameters associated with a geological region;
receiving, via the processing system, a physics-based model associated with performing a downhole operation of the geological region; and
integrating, via the processing system, the physics-based model with a neural network model to generate a physics-informed neural network (PINN) model associated with the downhole operation in the geological region.

2. The method of claim 1, wherein the downhole operation is a wireline operation.

3. The method of claim 1, wherein the neural network model comprises a multilayer perceptron neural network model.

4. The method of claim 1, wherein integrating the physics-based model with the neural network model includes constraining the neural network model based on one or more properties associated with the physics-based model.

5. The method of claim 1, comprising:
accessing historical data associated with the downhole operation, the geological region, or a combination thereof; and
updating the PINN model based on the historical data.

6. The method of claim 1, comprising:
generating one or more commands for downhole equipment associated with the downhole operation in the geological region based on the PINN model; and
sending the one or more commands to the downhole equipment, wherein the downhole equipment is configured to adjust the downhole operation based on the one or more commands.

7. The method of claim 6, wherein the downhole equipment comprises a wireline conveyance tool.

8. A system, comprising:
computer-readable storage media storing one or more instructions; and
a processing system coupled to the computer-readable storage media and configured to execute the one or more instructions, wherein executing the one or more instructions is configured to cause the processing system to:
receive or generate a request to predict one or more parameters associated with a geological region;
access a physics-based model associated with performing a downhole operation in the geological region; and
integrate the physics-based model with a neural network model to generate a physics-informed neural network (PINN) model associated with the downhole operation in the geological region.

9. The system of claim 8, wherein the physics-based model is associated with performing a wireline operation within the geological region.

10. The system of claim 8, wherein the neural network model comprises a multilayer perceptron neural network model.

11. The system of claim 8, wherein integrating the physics-based model with the neural network model includes constraining the neural network model based on one or more properties associated with the physics-based model.

12. The system of claim 8, wherein the executing the one or more instructions is configured to further cause the processing system to:
access historical data associated with the downhole operation, the geological region, or a combination thereof; and
update the PINN model based on the historical data.

13. The system of claim 8, wherein executing the one or more instructions is configured to further cause the processing system to:
generate one or more commands for downhole equipment associated with the geological region based on the PINN model; and
send the one or more commands to the downhole equipment, wherein the downhole equipment is configured to adjust the downhole operation based on the one or more commands.

14. The system of claim 13, wherein the downhole equipment comprises a wireline conveyance tool.

15. A computer-readable storage medium comprising:
computer-executable instructions that, when executed by a processing system, are configured to cause the processing system to:
process a request to predict one or more parameters associated with a geological region;
access a physics-based model associated with performing a downhole operation in the geological region; and
integrate the physics-based model with a neural network model to generate a physics-informed neural network (PINN) model associated with the downhole operation in the geological region.

16. The computer-readable storage medium of claim 15, wherein the downhole operation is a wireline operation within the geological region.

17. The computer-readable storage medium of claim 15, wherein the neural network model comprises a multilayer perceptron neural network model.

18. The computer-readable storage medium of claim 15, wherein integrating the physics-based model with the neural network model comprises constraining the neural network model based on one or more properties associated with the physics-based model.

19. The computer-readable storage medium of claim 15, wherein the computer-executable instructions, when executed by the processing system, are further configured to cause the processing system to:
access historical data associated with performing the downhole operation or the geological region; and
update the PINN model based on the historical data.

20. The computer-readable storage medium of claim 15, wherein the computer-executable instructions, when executed by the processing system, are further configured to cause the processing system:
generate one or more commands for downhole equipment associated with the geological region based on the PINN model; and
send the one or more commands to the downhole equipment, wherein the downhole equipment is configured to adjust the downhole operation based on the one or more commands.
